(19) United States
(12) Patent Application Publication
(10) Pub. No.: US 2011/0133154 A1
(43) Pub. Date: Jun. 9, 2011

(54) LIGHT-EMITTING DEVICE

(75) Inventors: Akira Tanaka, Kanagawa-ken (JP); Yoko Motojima, Kanagawa-ken (JP)

(73) Assignee: KABUSHIKI KAISHA TOSHIBA, Tokyo (JP)

(21) Appl. No.: 12/782,925

(22) Filed: May 19, 2010

(30) Foreign Application Priority Data
Dec. 8, 2009 (JP) 2009-278665

(51) Int. Cl. H01L 33/04; H01L 33/30; H01L 33/36

(52) U.S. Cl. 257/13; 257/103; 257/E33.008; 257/E33.023; 257/E33.062

(57) ABSTRACT

A light emitting device includes: a laminated body including a first conductivity type layer, a light emitting layer provided on the first conductivity type layer, and a second conductivity type layer provided on the light emitting layer, the laminated body being made of InₓGa_{y}Al_{1-x-y}N (0≦x≦1, 0≦y≦1, x+y≦1); a first electrode provided on the first conductivity type layer exposed to a bottom surface of a step difference provided in the laminated body; a translucent electrode provided on one portion of an upper face of the second conductivity type layer; and a second electrode provided on the translucent electrode and being smaller than the translucent electrode. A length of the other portion of the upper face of the second conductivity layer between an end portion of the translucent electrode and the side face of the step difference is 30 μm or more along a line connecting between a center of the first electrode and a center of the second electrode.

### CROSS-REFERENCE TO RELATED APPLICATIONS

This application is based upon and claims the benefit of priority from the prior Japanese Patent Application No. 2009-278665, filed on Dec. 8, 2009; the entire contents of which are incorporated herein by reference.

### BACKGROUND

In a visible light emitting element with a translucent electrode on the chip upper face, it is possible to extract light above the chip without shielding it while diffusing current generally horizontally in the translucent electrode parallel to the light emitting layer.

For a blue light emitting element, its volume productivity can be improved by using a sapphire or other insulating substrate as a substrate for crystal growth of a laminated body including a light emitting layer and made of a nitride semiconductor. In this structure, the current flows in the laminated body while spreading horizontally and vertically. In this case, a step difference is often provided between the upper electrode and the lower electrode for electrical connection.

JP-A-2008-010840 discloses a nitride semiconductor light emitting element including a translucent electrode, which can improve light emission uniformity and reduce the forward voltage Vf. In this example, the p-side pad electrode formed on the translucent electrode surface is disposed so as to satisfy a prescribed positional relation.

### SUMMARY

According to an aspect of the invention, there is provided a light emitting device including: a laminated body including a first conductivity type layer, a light emitting layer provided on the first conductivity type layer, and a second conductivity type layer provided on the light emitting layer, the laminated body being made of InₓGa_{y}Al_{1-x-y}N (0≦x≦1, 0≦y≦1, x+y≦1); a first electrode provided on the first conductivity type layer exposed to a bottom surface of a step difference provided in the laminated body; a translucent electrode provided on one portion of an upper face of the second conductivity type layer and apart from a side face of the step difference; and a second electrode provided on the translucent electrode and being smaller than the translucent electrode in a plan view, the trans lucent electrode being not provided on the other portion of the upper face of the second conductivity layer and a length of the upper face of the second conductivity layer between an end portion of the translucent electrode and a side face of the step difference being 30 μm or more along a line connecting between a center of the first conductivity type electrode and a center of the second electrode in the plan view.

According to another aspect of the invention, there is provided a light emitting device including: a laminated body including a first conductivity type layer, a light emitting layer provided on the first conductivity type layer, and a second conductivity type layer provided on the light emitting layer, the laminated body being made of InₓGa_{y}Al_{1-x-y}N (0≦x≦1, 0≦y≦1, x+y≦1); a first electrode provided on the first conductivity type layer exposed to a bottom surface of a step difference provided in the laminated body; a translucent electrode provided on one portion of an upper face of the second conductivity type layer and apart from a side face of the step difference; and a second electrode provided on the translucent electrode and being smaller than the translucent electrode in a plan view, the translucent electrode being not provided on the other portion of the upper face of the second conductivity type layer, a length of the other portion of the upper face of the second conductivity layer between one end portion of the translucent electrode and a side face of the step difference being 30 μm or more along a line connecting between a center of the first conductivity type electrode and a center of the second electrode in the plan view, and a length of the light emitting layer on the line being larger than a length of the light emitting layer in a direction parallel to a major surface of the light emitting layer and orthogonal to the line.

According to another aspect of the invention, there is provided a light emitting device including: a laminated body including a first conductivity type layer, a light emitting layer provided on the first conductivity type layer, and a second conductivity type layer provided on the light emitting layer, the laminated body being made of InₓGa_{y}Al_{1-x-y}N (0≦x≦1, 0≦y≦1, x+y≦1); a translucent electrode provided on one portion of one face of the laminated body and inside side faces of the laminated body in a plan view; a second electrode provided on the translucent electrode and being smaller than the translucent electrode in the plan view; a first conductivity type substrate; a current blocking layer provided on a portion of the other face of the laminated body opposite to the one face and being larger than the second electrode in the plan view; and a first electrode covering the other portion of the other face of the laminated body and the current blocking layer and joined to the first conductivity type substrate, the translucent electrode being not provided on the other portion of the one face of the laminated body and a length of the other portion of the one face of the laminated body between an outer edge portion of the translucent electrode and the side faces of the laminated body being 30 μm or more in the plan view.

### BRIEF DESCRIPTION OF THE DRAWINGS

FIGS. 1A and 1B are schematic views of a light emitting device according to a first embodiment;

FIG. 2A is a graph showing optical intensity distribution and FIG. 2B is a graph showing optical output characteristics;

FIG. 3 is a graph showing optical intensity distribution;

FIG. 4 is a graph showing optical intensity distribution;

FIGS. 5A to 5C are views describing a light emitting device according to a comparative example;

FIG. 6 is a graph showing optical absorption by ITO;

FIGS. 7A and 7B are graphs showing optical output characteristics in the MQW structure;

FIGS. 8A and 8B are schematic views of a light emitting device according to a second embodiment;

FIGS. 9A to 9C are schematic views of a light emitting device according to a third embodiment;

FIG. 10 is a schematic cross-sectional view of a light emitting device according to a fourth embodiment; and

FIG. 11 is a schematic cross-sectional view of a light emitting device according to a fifth embodiment.

### DETAILED DESCRIPTION

Embodiments of the invention will now be described with reference to the drawings.

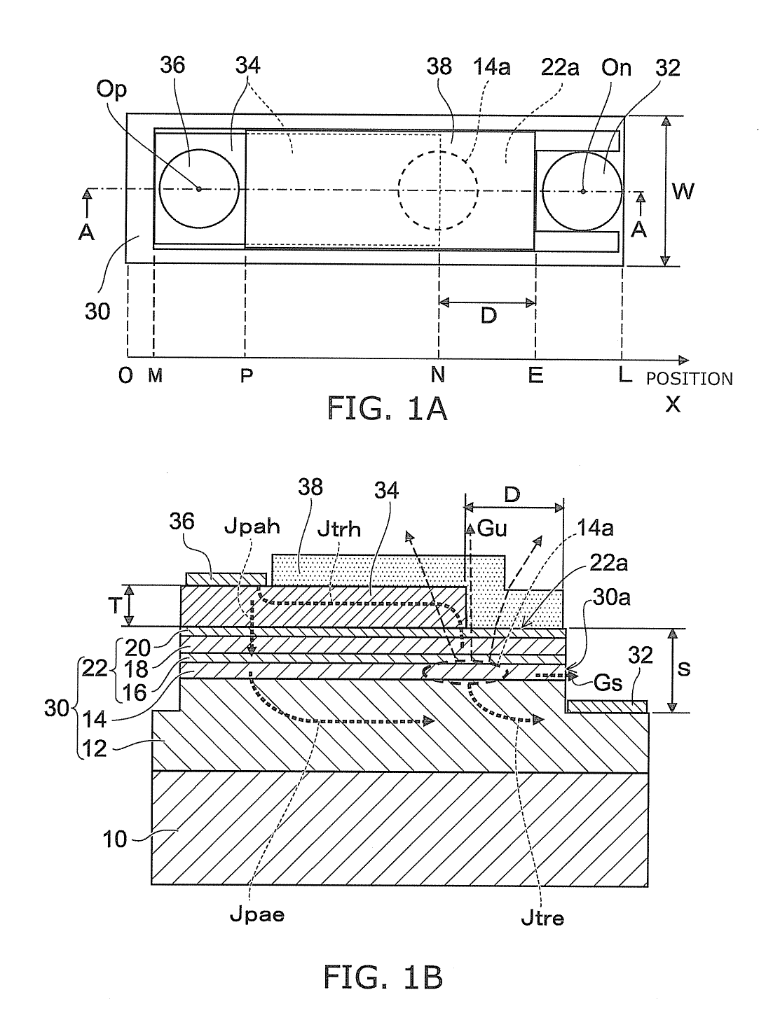

FIG. 1A is a schematic plan view of a light emitting device according to a first embodiment, and FIG. 1B is a schematic cross-sectional view taken along line A-A. This light emitting device is made of a nitride semiconductor represented by the composition formula InₓGa_{y}Al_{1-x-y}N (0≦x≦1, 0≦y≦1, x+y≦1) and can emit light in the ultraviolet to green wavelength range.

The light emitting device according to this embodiment includes a translucent and insulative substrate 10 illustratively made of sapphire, a laminated body 30 provided on the substrate 10, an n-side (first) electrode 32, a translucent electrode 34 provided on the laminated body 30, and a p-side pad (second) electrode 36 provided on the translucent electrode 34.

The laminated body 30 has a structure in which an n-type (first conductivity type) layer 12 serving as a cladding layer, a light emitting layer 14, and a p-type (second conductivity type) layer 22 are laminated in this order. The p-type layer 22 includes an overflow blocking layer 16, a p-type cladding layer 18, and a p-type contact layer 20 from the light emitting layer 14 side. The laminated body 30 like this can be formed illustratively by the MOCVD (metal organic chemical vapor deposition) process or the MBE (molecular beam epitaxy) process.

For instance, the n-type layer 12 is made of GaN with a thickness of 2.0 μm. The light emitting layer 14 has a multiple quantum well (MQW) structure made of In_{0.2}Ga_{0.8}N/In_{0.05}Ga_{0.95}N. The well layer thickness is 2.5 nm, the barrier layer thickness is 10 nm, and the number of wells is illustratively eight. The overflow blocking layer 16 is made of p-type Al_{0.15}Ga_{0.85}N with a thickness of e.g. 10 nm. The p-type cladding layer 18 is made of GaN with a thickness of e.g. 40 nm. The p-type contact layer 20 is illustratively made of GaN with a thickness of 5 nm.

The composition of the MQW is not limited to the above structure, but may include a well layer made of InₓGa_{y}Al_{1-x-y}N (0<x≦1, 0<y≦1, x+y≦1) and a barrier layer made of In_{z}Ga_{w}Al_{1-z-w}N (0≦z≦1, 0<w≦1, z+w≦1). The MQW structure facilitates effectively confining carriers in the well layer to increase the light emission efficiency.

In the laminated body 30 crystal grown on the substrate 10, a portion corresponding to a step difference is removed from the front side illustratively by the etching process to expose a flat surface of the n-type layer 12 with depth S. The n-side electrode 32 is provided on the n-type layer 12 exposed to the bottom face of the step difference. By using the dry etching process, the side face 30a of the step difference of the laminated body 30 can be made nearly vertical. The side face 30a (first side face) is opposed to the n-side electrode 32 side.

In FIG. 1A, on line A-A connecting between the center Op (or barycenter) of the p-side pad electrode 36 and the center On (or barycenter) of the n-side electrode 32, the horizontal position is represented by X (μm) with the origin at the side face of the chip on the p-side pad electrode 36 side. The translucent electrode 34 is provided between M and N of the horizontal position X on the upper face of the p-type layer 22. The region in the horizontal position X between one end portion (position N) of the translucent electrode 34 and the position E of the side face 30a of the step difference is defined as an electrode non-forming region 22a, whose length is denoted by D. That is, one end portion of the translucent electrode 34 is apart from the side face 30a by D. Furthermore, the p-side pad electrode 36 smaller than the translucent electrode 34 is provided on the other end portion (position M) side. The translucent electrode 34 can illustratively be made of indium tin oxide (ITO), zinc oxide (ZnO), or tin oxide (SnO₂). Among them, ITO is preferable because it can reduce sheet resistance more effectively.

In this embodiment, holes injected from the p-side pad electrode 36 form a current Jtrh, which spreads horizontally in the translucent electrode 34 and flows vertically in the p-type contact layer 20, the p-type cladding layer 18, and the overflow blocking layer 16. In order for the current Jtrh to flow in the horizontal plane with a uniform current density, the light emitting layer 14 is preferably shaped like a rectangle longer in the direction of line A-A as in FIG. 1A. For instance, the long side length L is 500 μm, the short side length W is 180 μm, and the circle diameter of the p-side pad electrode 36 and the n-side electrode 32 is 80 μm. It is understood that the electrode is not limited to a circular shape, but may be rectangular, elliptic and the like. Furthermore, the current distribution in the light emitting layer 14 can be made more uniform near the end portion if the end portion of the laminated body 30 surrounds the n-side electrode 32 from three directions.

In this embodiment, the region (N<X<E) between one end portion of the translucent electrode 34 and the side face 30a of the step difference of the laminated body 30 is defined as the electrode non-forming region 22a where the translucent electrode 34 is not provided. As viewed from above (in a plan view), the length of the electrode non-forming region 22a along line A-A is denoted by D.

The p-type layer 22 made of a nitride semiconductor with a refractive index between 2.5 and 2.7 is exposed to the upper face of the electrode non-forming region 22a. The light extraction efficiency can be increased by covering the upper face of the electrode non-forming region 22a with a dielectric film 38 having a refractive index between the refractive index of the p-type layer 22 and that of the air layer. The dielectric film 38 can illustratively be a silicon oxide film (SiO₂) having a refractive index of generally 1.5 or a silicon nitride film (Si₃N₄) having a refractive index between 1.9 and 2.1. For instance, it is assumed that the p-type layer 22 has a refractive index of 2.6, and the dielectric film 38 has a refractive index of 2.0. Reflection and transmission of light at the interface of different refractive indices obey the Fresnel equation. It is assumed that the incident angle is not significantly large and set to zero in the Fresnel equation. In this case, the power transmission coefficient T from a medium with refractive index n1 to a medium with refractive index n2 does not depend on the polarization direction, and can be approximated by equation (1):

T=4×n1×n2/(n1+n2)² (1)

The power transmission coefficient for emission from the p-type layer 22 having a refractive index of 2.6 to the air layer having a refractive index of 1 is generally 80% from equation (1). On the other hand, the power transmission coefficient T for emission from the p-type layer 22 to the dielectric film 38 having a refractive index of 2.0 is generally 98%. Furthermore, the power transmission coefficient T for emission from the dielectric film 38 to the air layer is generally 89%. Thus, if the dielectric film 38 is provided on the upper face of the electrode non-forming region 22a, the total power transmission coefficient is given by the product of the two power transmission coefficients and approximated to generally 87%, and thus the light extraction efficiency on the upper side can be increased. Furthermore, the refractive index of ITO ranges from 2.0 to 2.2, exhibiting a small difference from the refractive index of the dielectric film 38. This facilitates aligning the refraction direction for emission to the outside such as the air layer to reduce variation in directional characteristics.

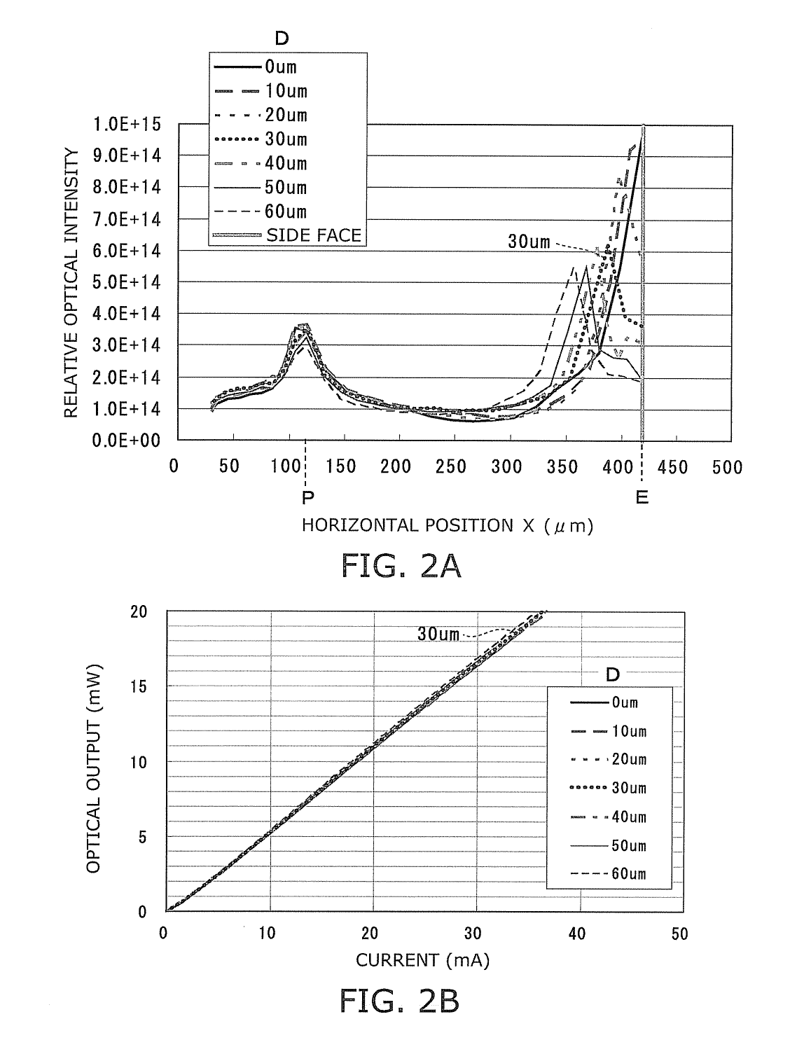

FIGS. 2A and 2B are graphs of optical intensity distribution and optical output, respectively, obtained by simulation.

In FIG. 2A, the vertical axis represents relative optical intensity in the light emitting layer 14, and the horizontal axis represents the horizontal position X (μm). In this figure, the length D is set to 0, 10, 20, 30, 40, 50, and 60 μm. The horizontal position X of the side face 30a of the step difference of the laminated body 30 is located near 420 μm, denoted by E. The horizontal position X of one end portion of the p-side pad electrode 36 is located near 110 μm, denoted by P. Here, the translucent electrode 34 is made of ITO with a resistivity of 3×10⁻⁴ Ω·cm and a thickness T of 0.25 μm. It is assumed that the chip is surrounded by the air layer.

The length D equal to zero indicates that one end portion of the translucent electrode 34 is generally aligned with the side face 30a of the step difference as viewed from above. In this case, the optical intensity is maximized at the position E. That is, holes injected from the p-side pad electrode 36 form a current Jtrh, which flows horizontally in the translucent electrode 34 toward the n-side electrode 32 and further flows downward along the side face 30a of the step difference of the laminated body 30 into the light emitting layer 14. On the other hand, electrons injected from the n-side electrode 32 form a current Jtre flowing in the n-type layer 12. Holes and electrons recombine in the light emitting layer 14 to emit light. Thus, the optical intensity is maximized near the light emitting layer 14 exposed to the side face 30a.

On the other hand, holes injected from the p-side pad electrode 36 in a direction generally perpendicular to the translucent electrode 34 and the laminated body 30 form a current Jpah flowing into the light emitting layer 14. On the other hand, electrons injected from the n-side electrode 32 form a current Jpae passing through the n-type layer 12 and flowing into the light emitting layer 14. Holes and electrons recombine in the light emitting layer 14 to emit light, giving a sub-peak of optical intensity near the position P. In this case, because of the p-side pad electrode 36 provided above, part of the emission light is shielded, reducing light which can be extracted from the upper side.

In gallium nitride-based materials, there is a limit to increasing the hole concentration, and the hole current is typically lower than the electron current. The overflow blocking layer 16 has a high hole carrier concentration and a high heterobarrier height on a conduction band edge side, and hence can effectively confine electrons in the light emitting layer 14. Hence, it reduces the electron current not contributing to radiative recombination. That is, the sum of the hole-induced current and the electron-induced current can be made constant in the path between the p-side pad electrode 36 and the n-side electrode 32. Furthermore, the overflow blocking layer 16 can serve so that the hole current primarily flows on the p-side pad electrode 36 side and the electron current primarily flows on the n-side electrode 32 side. Although the first conductivity type is n-type and the second conductivity type is p-type in this embodiment, the conductivity types may be reversed.

It turns out from the simulation result shown in FIG. 2A that the peak position of optical intensity is located in an underlying region 14a below one end portion of the translucent electrode 34. Furthermore, it turns out that the peak value of optical intensity decreases as the length D becomes longer. In the case where the length D is 20 μm or less, the optical intensity at the position E corresponding to the side face is as high as 73% or more of the peak value, increasing light Gs emitted laterally from the chip and decreasing the intensity of light Gu which can be extracted above. This tends to cause horizontal asymmetry of upward directional characteristics in the cross section taken along line A-A.

In contrast, in the case where the length D is 30 μm or more, the optical intensity at the side face 30a can be made 60% or less of the peak value. This can reduce light Gs emitted laterally and increase the intensity of light Gu which can be extracted from the upper side.

FIG. 2B shows optical output calculated from the operating voltage, operating current, light emission efficiency and the like. It turns out that variation in optical output is small even if the variation of the length D causes variation of the current path and the peak position and peak value of optical intensity. In this embodiment, the length D set to 30 μm or more facilitates increasing the light extraction efficiency on the upper side and achieving horizontal symmetry of directional characteristics in the cross section taken along line A-A.

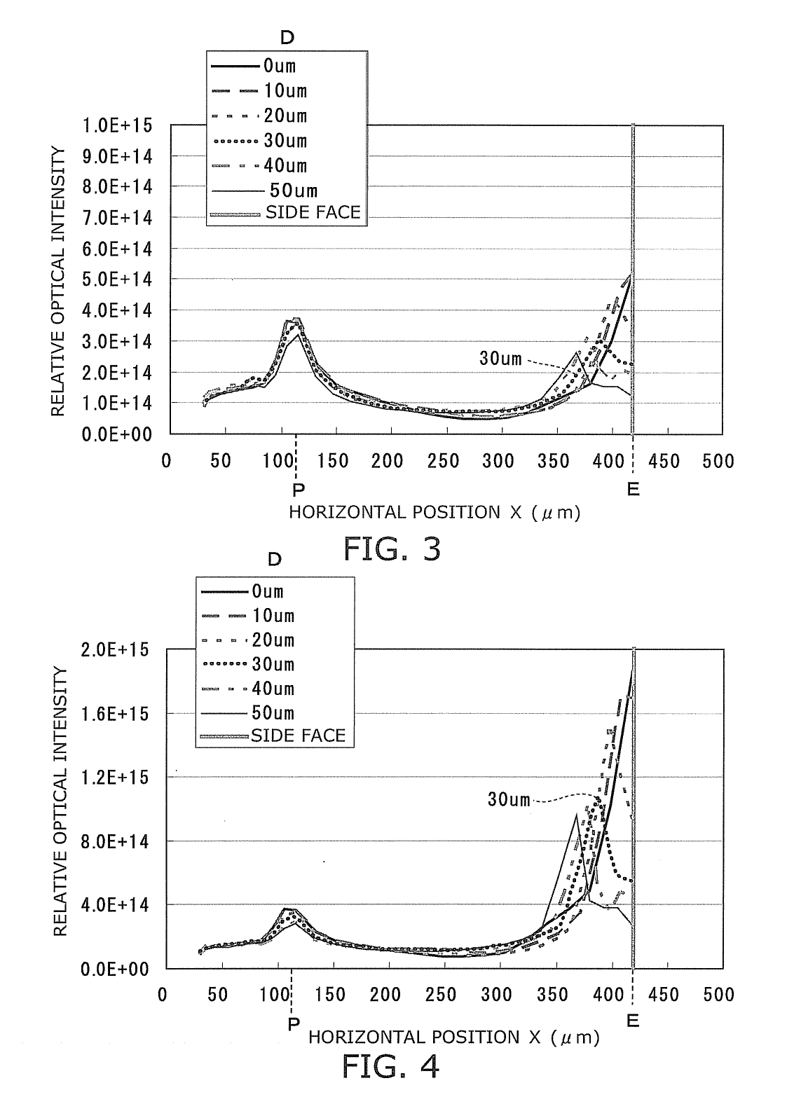

FIG. 3 is a graph of optical intensity distribution for ITO with a resistivity of 3×10⁻⁴ Ω·cm and a thickness T of 0.1 μm.

The thickness T of the translucent electrode 34 is small, making it difficult for the current to flow therein horizontally. The current flowing vertically from the neighborhood of one end portion of the translucent electrode 34 and being able to contribute to recombination in the light emitting layer 14 is lower than the current in the case where the ITO thickness T is 0.25 μm (FIG. 2A). This results in decreasing the optical intensity. However, even in this case, if the length D is 30 μm or more, the optical intensity at the side face 30a can be made 60% or less of the peak value of optical intensity, and the light extraction efficiency on the upper side can be increased.

FIG. 4 is a graph of optical intensity distribution for ITO with a resistivity of 3×10⁻⁴ Ω·cm and a thickness of 0.5 μm.

The thickness T of the translucent electrode 34 is large, making it easier for the current to flow than in FIGS. 2A, 2B, and 3. The current flowing vertically from the neighborhood of one end portion of the translucent electrode 34 and being able to contribute to recombination is higher than the current in the case where the ITO thickness T is 0.25 μm (FIG. 2A). If the length D is 30 μm or more, the optical intensity at the side face 30a can be made 56% or less of the peak value of optical intensity, and the light extraction efficiency on the upper side can be increased. Here, if the chip is covered with a sealing resin layer, the refractive index difference is decreased, and hence the optical intensity at the side face 30a is increased. Thus, it is preferable to increase the length D to reduce lateral emission light Gs.

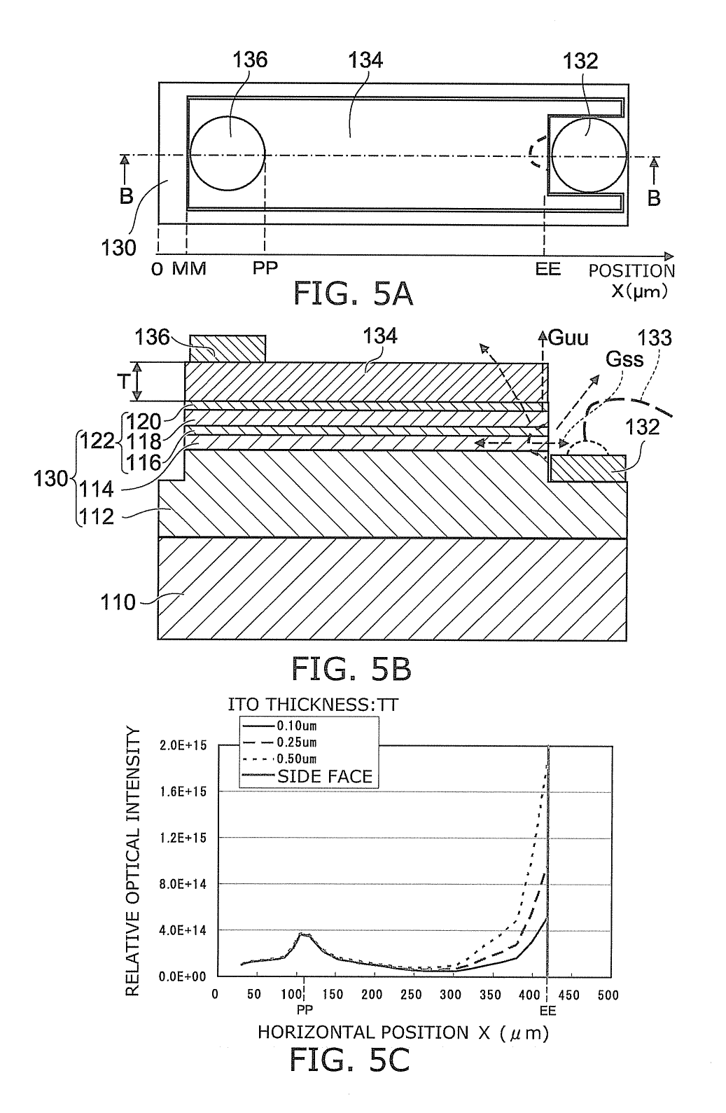

FIG. 5A is a schematic plan view of a light emitting device according to a comparative example, FIG. 5B is a schematic cross-sectional view taken along line B-B, and FIG. 5C is a graph showing the optical intensity distribution thereof. A laminated body 130 is formed on a substrate 110. The laminated body 130 has a structure in which an n-type layer 112, a light emitting layer 114, and a p-type layer 122 are laminated in this order. The p-type layer 122 includes an overflow blocking layer 116, a p-type cladding layer 118, and a p-type contact layer 120.

An n-side electrode 132 is provided on the n-type layer 112 exposed to the bottom face of the step difference provided in the laminated body 130. On the other hand, a translucent electrode 134 made of ITO is provided between MM and EE of the horizontal position X on the p-type contact layer 120. Furthermore, a p-side pad electrode 136 is formed on the translucent electrode 134. The current injected from the p-side pad electrode 136 and directed horizontally in the translucent electrode 134 flows vertically along the side face 130a of the step difference near the n-side electrode 132. Hence, the optical intensity is maximized near the side face 130a, increasing laterally directed light Gss and decreasing the light extraction efficiency on the upper side.

Because the n-side electrode 132 and the bonding wire 133 are provided near the maximum of optical intensity, the emission light Gss is scattered. This is undesirable because the emission light Gss is not effectively extracted above and the directional characteristics are disturbed.

For ITO with a resistivity of 3×10⁻⁴ Ω·cm and a thickness of 0.1 μm, the sheet resistance given by the resistivity divided by the thickness is 30Ω, and the relative optical intensity is close to the optical intensity near the position PP. In the case where the ITO thickness is 0.25 μm, the sheet resistance is 12Ω, and the peak value of optical intensity can be increased to generally 1.8 times the peak value of optical intensity for 0.1 μm, and in the case where the ITO thickness is 0.5 μm, the sheet resistance is 6Ω, and the peak value of optical intensity can be increased to generally 3.6 times the peak value of optical intensity for 0.1 μm. That is, because the sheet resistance decreases as the ITO thickness becomes larger, the proportion of the current flowing to the p-type layer 122 between the positions PP and EE decreases. On the other hand, below the p-side pad electrode 136, the current flowing in the direction perpendicular to ITO has a small variation with respect to the ITO thickness, and the variation in optical intensity is small.

As described above, the inventors have discovered that in a light emitting device made of a nitride semiconductor, lateral emission light Gs can be reduced by setting the length D to 30 μm or more. This lower limit length, 30 μm, has little dependence on the thickness T and sheet resistance of the translucent electrode 34, and is primarily determined by the relative relationship between the refractive index of the nitride semiconductor ranging from 2.5 to 2.7 and the external refractive index.

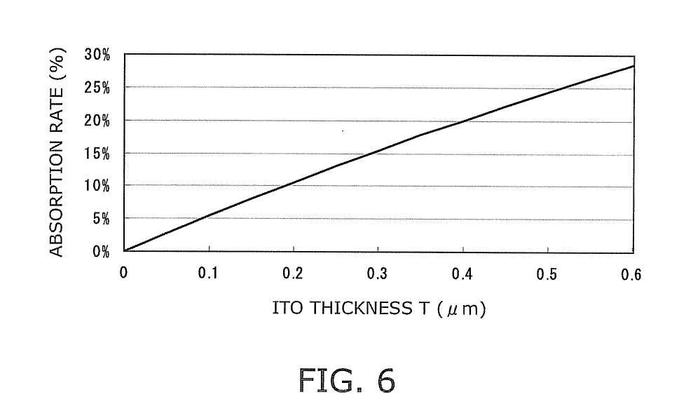

FIG. 6 is a graph showing optical absorption by ITO.

The vertical axis represents absorption rate (%), and the horizontal axis represents ITO thickness T (μm). The absorption rate increases with the increase of ITO thickness T. For instance, the absorption rate is generally 5% for a thickness T of 0.1 μm, whereas the absorption rate is increased to generally 13% for a thickness T of 0.25 μm. The absorption rate is further increased to generally 24% for a thickness T of 0.5 μm. That is, increase in ITO thickness T facilitates increasing the peak value of optical intensity, but also increases the optical absorption rate, which results in decreasing the light extraction efficiency.

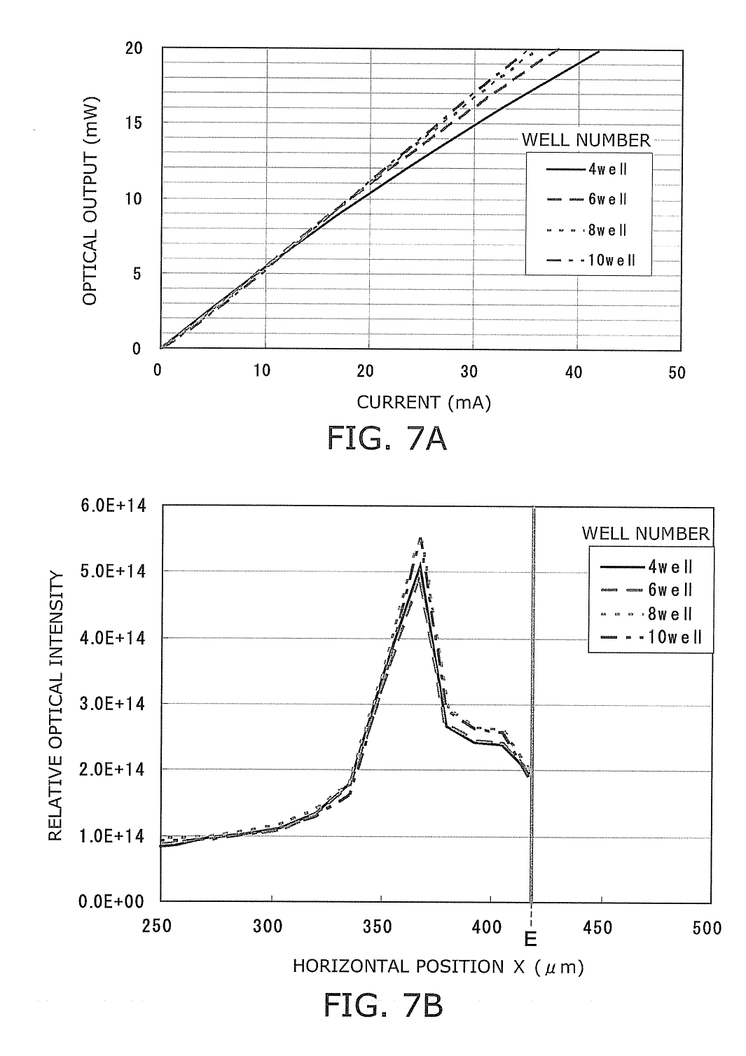

FIG. 7A is a graph showing optical output characteristics in the MQW structure, and FIG. 7B is a graph showing the optical intensity distribution thereof. Here, the length D is set to 50 μm.

In FIG. 7A, the vertical axis represents optical output (mW), and the horizontal axis represents current (mA). With the number of wells in the MQW structure being set to 4, 6, 8, and 10, the difference in optical output is small up to near a current of 15 mA. When the current is increased to near 30 mA, the optical output increases as the number of wells becomes larger. On the other hand, in FIG. 7B, the vertical axis represents relative optical intensity, and the horizontal axis represents the horizontal position X (μm). The peak value of optical intensity slightly increases with the increase in the number of wells, but the variation in the peak position and optical intensity distribution is small. That is, it turns out that the optical intensity distribution has little dependence on the MQW structure.

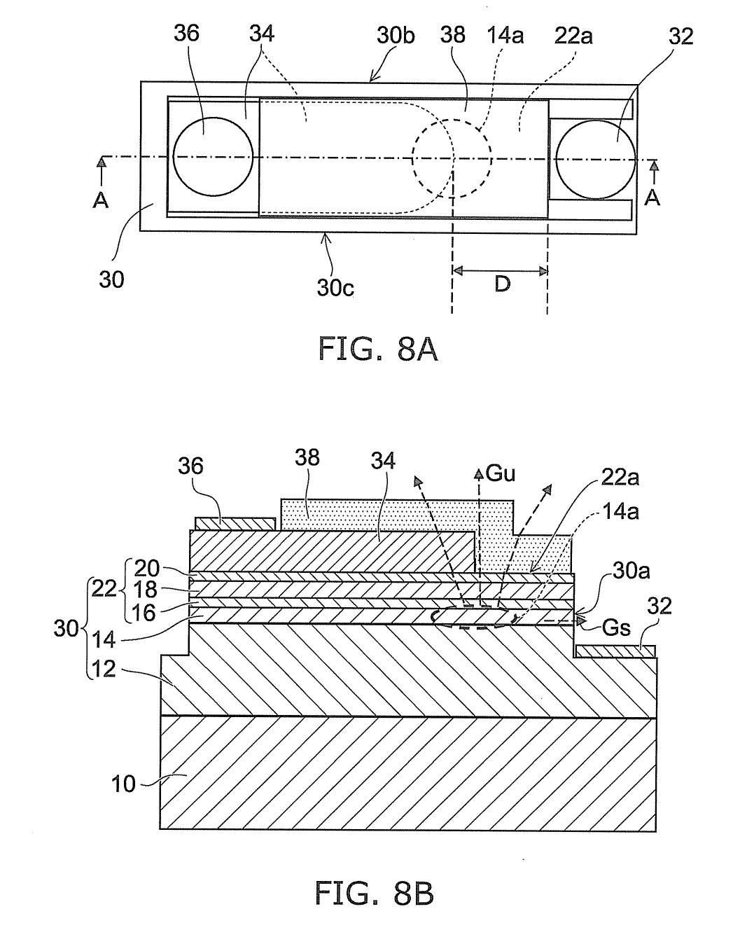

FIG. 8A is a schematic plan view of a light emitting device according to a second embodiment, and FIG. 8B is a schematic cross-sectional view taken along line A-A.

One end portion of the translucent electrode 34 has a convex shape toward the n-side electrode 32 as viewed from above. This can further increase the optical intensity in the underlying region 14a where the convex portion of the translucent electrode 34 crosses line A-A. Thus, emission light from the side faces 30b, 30c of the laminated body 30 parallel to line A-A can be reduced.

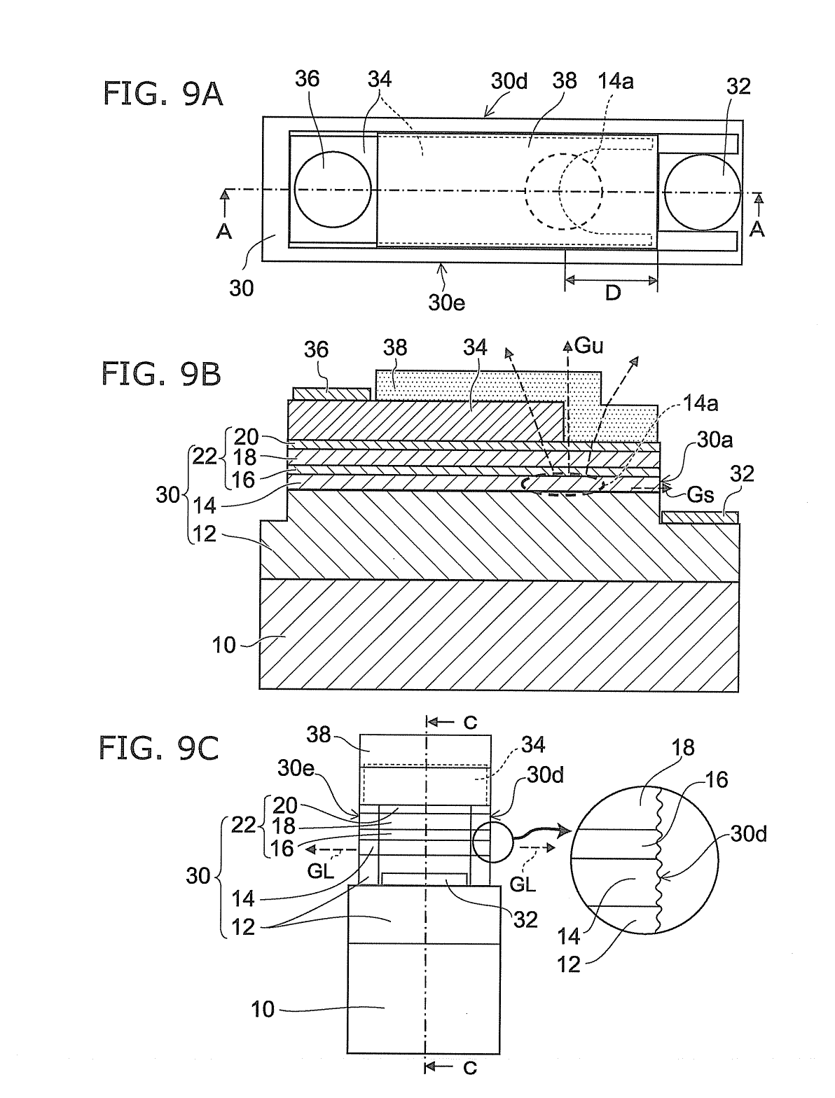

FIG. 9A is a schematic plan view of a light emitting device according to a third embodiment, FIG. 9B is a schematic cross-sectional view taken along line A-A, and FIG. 9C is a side view.

Emission light GL from the side faces 30d, 30e of the laminated body 30 parallel to line A-A is not scattered by the n-side electrode 32 or the bonding wire, but emitted generally in a horizontally symmetric manner with respect to line C-C of FIG. 9C. Even if the emission light GL is difficult to extract upward directly through the translucent electrode 34, it can be reflected upward illustratively by a reflector provided in the package to increase the light extraction efficiency.

In this case, as shown in FIG. 9A, as viewed from above, if one end portion of the translucent electrode 34 has a concave shape toward the n-side electrode 32, emission light GL from the side faces 30d, 30e or upward emission light Gu can be increased while suppressing lateral emission on the n-side electrode 32 side. Furthermore, if a fine unevenness is formed on the side faces 30d, 30e by a surface roughening process, total reflection is reduced at the side faces 30d, 30e, and the light extraction efficiency can be further increased.

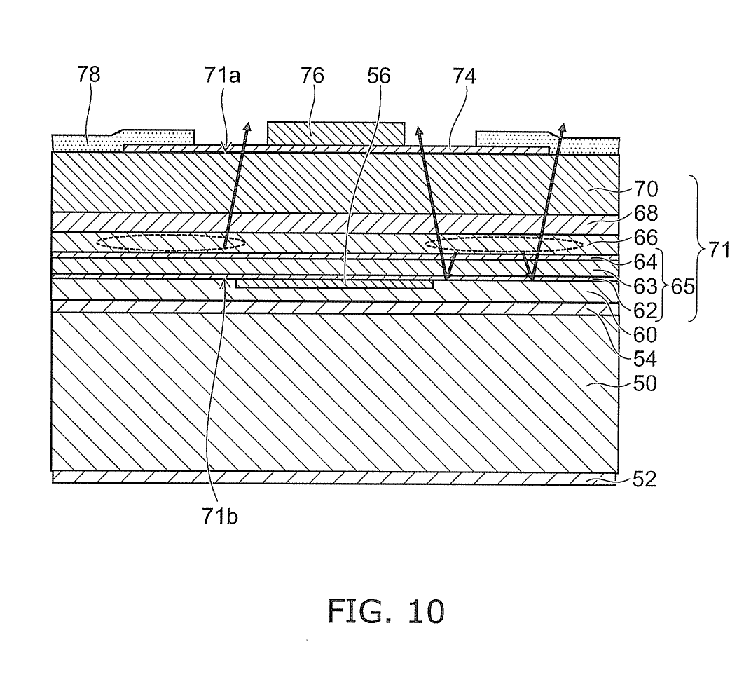

FIG. 10 is a schematic cross-sectional view of a light emitting device according to a fourth embodiment.

In this embodiment, a laminated body 71 including a light emitting layer 66 is provided on a support substrate 50, which is different from the crystal growth substrate. This laminated body 71 includes no step difference. The laminated body 71 illustratively includes a p-type layer 65, a light emitting layer 66, an n-type superlattice layer 68, and an n-type layer 70.

The p-type layer 65 illustratively includes a contact layer (5 nm thick) 62 made of p⁺-type GaN, a p-type GaN layer (40 nm thick) 63, and a p-type Al_{0.15}Ga_{0.85}N layer (10 nm thick) 64. The light emitting layer 66 can have a multiple quantum well (MQW) structure in which, for instance, well layers each made of In_{0.2}Ga_{0.8}N with a thickness of 2.5 nm and barrier layers each made of In_{0.05}Ga_{0.95}N with a thickness of 10 nm are alternately laminated. The number of wells can illustratively be eight. Furthermore, the n-type superlattice layer 68 can have a structure in which 20 pairs of In_{0.2}Ga_{0.8} with a thickness of 1 nm and GaN with a thickness of 2 nm are laminated.

A substrate lower electrode 52 and a substrate upper electrode 54 are provided on the lower face and upper face of the support substrate 50, respectively. The support substrate 50 can be made of a conductive material such as Si and SiC. The laminated body 71 is illustratively crystal grown on a sapphire substrate from one face 71a side. Subsequently, a current blocking layer 56 illustratively made of dielectric, and a p-side electrode 60 are formed in this order on the other face 71b of the laminated body 71. If the p-side electrode 60 includes Al or Ag having a higher reflectance than Au on the other face 71b of the laminated body 71, emission light from the light emitting layer 66 can be reflected upward to increase the light extraction efficiency.

Furthermore, the p-side electrode 60 provided on the other face 71b side of the laminated body 71 is bonded to the support substrate 50 by a thermal compression bonding method. Then, the p-side electrode 60 is joined to the support substrate 50 via the substrate upper electrode 54. Subsequently, the sapphire substrate is removed. A translucent electrode 74 larger than the current blocking layer 56 as viewed from above is provided on one face 71a of the laminated body 71. The outer edge portion of the translucent electrode 74 is spaced 30 μm or more from each of the four side faces of the chip.

Furthermore, an n-side pad electrode 76 smaller than the current blocking layer 56 is provided on the translucent electrode 74. Flow of carriers, injected from the n-side pad electrode 76, into the light emitting layer 66 immediately below the n-side pad electrode 76 is suppressed because of the presence of the current blocking layer 56. This can reduce the amount of light shielded by the n-side pad electrode 76 to increase the light extraction efficiency. Furthermore, a dielectric film 78 is provided on part of the non-forming region of the translucent electrode 74 on one face 71a of the laminated body 71 and the non-forming region of the n-side pad electrode 76 on the translucent electrode 74. That is, light directed upward from the light emitting layer 66 is emitted upward through the translucent electrode 74. Because the end portion of the translucent electrode 74 is spaced 30 μm or more from each side face of the chip, the intensity of emission light directed to the side faces can be suppressed. This consequently facilitates further increasing the light extraction efficiency on the upper side. It is noted that the conductivity types are not limited to those in this embodiment, but may be reversed. Furthermore, the composition and thickness of each layer constituting the laminated body 71 are not limited to those in this embodiment.

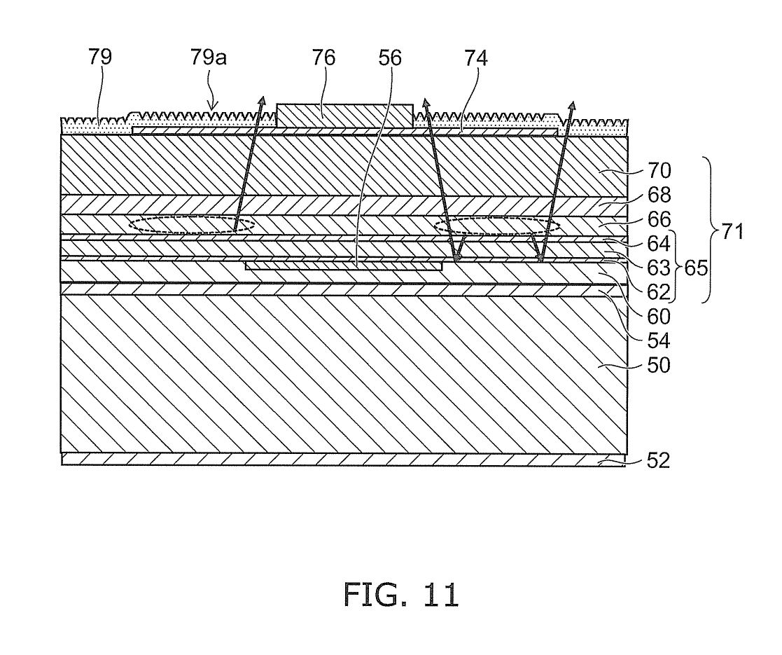

FIG. 11 is a schematic cross-sectional view of a light emitting device according to a fifth embodiment.

In this embodiment, the dielectric layer 79 is formed on the upper face of the chip except the n-side pad electrode 76. Furthermore, a fine unevenness 79a with a height illustratively ranging from 0.1 to 3 μm is formed on the surface of the dielectric layer 79. The surface with such an unevenness 79a expands the range of the crossing angle of light fluxes and reduces light totally reflected back into the chip. Thus, the light extraction efficiency can be further increased.

The embodiments of the invention have been described with reference to the drawings. However, the invention is not limited to these embodiments. Those skilled in the art can variously modify the material, shape, size, layout and the like of the laminated body, light emitting layer, p-type layer, p-side pad electrode, translucent electrode, n-side electrode, dielectric film and the like constituting the embodiments, and such modifications are also encompassed within the scope of the invention as long as they do not depart from the spirit of the invention.

1. A light emitting device comprising:
a laminated body including a first conductivity type layer, a light emitting layer provided on the first conductivity type layer, and a second conductivity type layer provided on the light emitting layer, the laminated body being made of InₓGa_{y}Al_{1-x-y}N (0≦x≦1, 0≦y≦1, x+y≦1);
a first electrode provided on the first conductivity type layer exposed to a bottom surface of a step difference provided in the laminated body;
a translucent electrode provided on one portion of an upper face of the second conductivity type layer and apart from a side face of the step difference; and
a second electrode provided on the translucent electrode and being smaller than the translucent electrode in a plan view,
the translucent electrode being not provided on the other portion of the upper face of the second conductivity type layer, and
a length of the other portion of the upper face of the second conductivity layer between an end portion of the translucent electrode and the side face of the step difference being 30 μm or more along a line connecting between a center of the first electrode and a center of the second electrode in the plan view.

2. The device according to claim 1, wherein the translucent electrode includes at least one of indium tin oxide, zinc oxide, and tin oxide.

3. The device according to claim 1, further comprising:
a dielectric film covering the other portion of the upper face of the second conductivity layer between the end portion of the translucent electrode and the side face of the step difference.

4. The device according to claim 3, wherein the dielectric film further covers a non-forming region of the second electrode on the translucent electrode.

5. The device according to claim 4, wherein the dielectric film includes an unevenness on a light extraction side.

6. The device according to claim 3, wherein the dielectric film includes silicon oxide or silicon nitride.

7. The device according to claim 1, wherein the light emitting layer includes a multiple quantum well including a well layer made of InₓGa_{y}Al_{1-x-y}N (0<x≦1, 0<y≦1, x+y≦1) and a barrier layer made of In_{z}Ga_{w}Al_{1-z-w}N (0≦z≦1, 0≦w≦1, z+w≦1).

8. A light emitting device comprising:
a laminated body including a first conductivity type layer, a light emitting layer provided on the first conductivity type layer, and a second conductivity type layer provided on the light emitting layer, the laminated body being made of InₓGa_{y}Al_{1-x-y}N (0≦x≦1, 0≦y≦1, x+y≦1);
a first electrode provided on the first conductivity type layer exposed to a bottom surface of a step difference provided in the laminated body;
a translucent electrode provided on one portion of an upper face of the second conductivity type layer and apart from a side face of the step difference; and
a second electrode provided on the translucent electrode and being smaller than the translucent electrode in a plan view,
the translucent electrode being not provided on the other portion of the upper face of the second conductivity type layer, and
a length of the other portion of the upper face of the second conductivity layer between an end portion of the translucent electrode and the side face of the step difference being 30 μm or more along a line connecting between a center of the first electrode and a center of the second electrode in the plan view, and
a length of the light emitting layer on the line being larger than a length of the light emitting layer in a direction parallel to a major surface of the light emitting layer and orthogonal to the line.

9. The device according to claim 8, wherein the translucent electrode includes the end portion having a convex shape toward the first electrode in the plan view.

10. The device according to claim 8, wherein the translucent electrode includes the end portion having a concave shape toward the first electrode in the plan view.

11. The device according to claim 10, wherein among side faces of the laminated body, two side faces perpendicular to the side face of the step difference include an unevenness, respectively.

12. A light emitting device comprising:
a laminated body including a first conductivity type layer, a light emitting layer provided on the first conductivity type layer, and a second conductivity type layer provided on the light emitting layer, the laminated body being made of InₓGa_{y}Al_{1-x-y}N (0≦x≦1, 0≦y≦1, x+y≦1);
a translucent electrode provided on one portion of one face of the laminated body and inside side faces of the laminated body in plan view;
a second electrode provided on the translucent electrode and being smaller than the translucent electrode in the plan view;
a first conductivity type substrate;
a current blocking layer provided on one portion of the other face of the laminated body opposite to the one face and being larger than the second electrode in the plan view; and
a first electrode covering the other portion of the other face of the laminated body and the current blocking layer and joined to the first conductivity type substrate,
the translucent electrode being not provided on the other portion of the one face of the laminated body, and
a length of the other portion of the one face of the laminated body between an outer edge portion of the translucent electrode and the side faces of the laminated body being 30 μm or more in the plan view.

13. The device according to claim 12, wherein the translucent electrode includes at least one of indium tin oxide, zinc oxide, and tin oxide.

14. The device according to claim 12, wherein the first electrode includes Al or Ag on the other face side of the laminated body.

15. The device according to claim 12, wherein the current block layer includes silicon oxide or silicon nitride.

16. The device according to claim 12, further comprising:
a dielectric film covering the other portion of the one face of the laminated body between the outer edge portion of the translucent electrode and the side faces of the laminated body.

17. The device according to claim 12, wherein the dielectric film further covers a non-forming region of the second electrode on the translucent electrode.

18. The device according to claim 17, wherein the dielectric film includes an unevenness on a light extraction side.

19. The device according to claim 17, wherein the dielectric film includes silicon oxide or silicon nitride.

20. The device according to claim 12, wherein the light emitting layer includes a multiple quantum well including a well layer made of InₓGa_{y}Al_{1-x-y}N (0<x≦1, 0<y≦1, x+y≦1) and a barrier layer made of In_{z}Ga_{w}Al_{1-z-w}N (0≦z≦1, 0≦w≦1, z+w≦1).
